(19) United States
(12) Patent Application Publication
(10) Pub. No.: US 2006/0194405 A1
(43) Pub. Date: Aug. 31, 2006

(54) Semiconductor device and method of fabricating the same

(76) Inventors: Hajime Nagano, Yokohama-Shi (JP); Kiyotaka Miyano, Fujisawa-Shi (JP); Osamu Arisumi, Yokohama-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/266,262

(22) Filed: Nov. 4, 2005

(30) Foreign Application Priority Data
Feb. 28, 2005 (JP) 2005-53634

(51) Int. Cl. H01L 21/76; H01L 29/00

(52) U.S. Cl. 438/400; 257/499

(57) ABSTRACT

A semiconductor device has an element isolating region formed of an insulating film having etching rates different from each other in a side close to an inside wall and a center side of a trench formed on a semiconductor substrate, and a selective epitaxial layer formed in both sides of the element isolating region, wherein the element isolating region has a tip portion in a tapered shape or a stepwise shape of which a width becomes narrower at a side closer to the tip portion.

### CROSS REFERENCE TO RELATED APPLICATIONS

This application is based upon and claims the benefit of priority from the prior Japanese Patent Application No. 2005-53634, filed on Feb. 28, 2005, the entire contents of which are incorporated herein by reference.

### BACKGROUND OF THE INVENTION

1. Field of the Invention

The present invention relates to a semiconductor device having a selective epitaxial layer, and a method for manufacturing the same.

2. Related Art

When a transistor is fabricated on an SOI (silicon on insulator) substrate, a joining region of the transistor must be formed on a location shallower than a surface of the substrate in order to avoid a short-channel effect, and inevitably, a source and a drain of the transistor are thinned. Therefore, there is a problem in which a parasitic resistance of a source and a drain of the transistor is increased and a power consumption of the transistor is also increased.

In order to solve such problems, an elevated source/drain structure in which an epitaxial layer is selectively formed on the source and drain has been proposed (refer to Japanese Patent Laid-Open Publications Nos. 2002-43407 and 2004-207680). Since an epitaxial layer also grows in a lateral direction substantially as much as in a direction of thickness, the epitaxial layers in two adjacent elements will be short-circuited with each other unless the distance between adjacent elements is longer than twice or more the thickness of the epitaxial layer.

As one of the measures to avoid this kind of short-circuiting, it is considered to suppress growth of the selective epitaxial layer in the lateral direction. In current technology, however, no specific methods for accurately suppress growth of the selective epitaxial layer only in the lateral direction have been known.

The short-circuiting of selective epitaxial layers located in both sides of an element isolating region between adjacent elements can be prevented if the element isolating region is formed as high as possible from the surface of the substrate. In this case, however, a crystal face known as a facet is formed in the selective epitaxial layer contacting the element isolating region. Therefore, a desired current cannot flow even if a specific voltage is applied to the selective epitaxial layer.

### SUMMARY OF THE INVENTION

According to one embodiment of the present invention, a semiconductor device, comprising:

an element isolating region formed of an insulating film having etching rates different from each other in a side close to an inside wall and a center side of a trench formed on a semiconductor substrate; and

a selective epitaxial layer formed in both sides of the element isolating region,

wherein the element isolating region has a tip portion in a tapered shape or a stepwise shape of which a width becomes narrower at a side closer to the tip portion.

Furthermore, according to one embodiment of the present invention, a method of fabricating a semiconductor device, comprising:

forming a trench in a region to form an element isolating region on a semiconductor substrate;

forming an insulating film having etching rates different from each other in a side close to an inside wall and a center side of a trench formed on a semiconductor substrate;

eliminating a portion of the insulating film by a CMP (Chemical Mechanical Polishing) process and an etching process to form the element isolating region having a tip portion in a tapered shape or a stepwise shape of which a width becomes narrower at a side closer to the tip portion; and

forming silicon grown epitaxially in both sides of the element isolating region to form a selective epitaxial layer.

### BRIEF DESCRIPTION OF THE DRAWINGS

FIG. 1 is a sectional view showing a cross-sectional structure of a semiconductor device according to an embodiment of the present invention.

FIG. 2 is a sectional view showing a comparative example of the semiconductor device shown in FIG. 1.

FIG. 3 is a sectional view showing the steps for manufacturing a semiconductor device.

FIG. 4 is a sectional view showing the steps subsequent to FIG. 3.

FIG. 5 is a sectional view showing the steps subsequent to FIG. 4.

FIG. 6 is a sectional view showing the steps subsequent to FIG. 5.

FIG. 7 is a sectional view showing the steps subsequent to FIG. 6.

FIG. 8 is a graph showing a correlation between the pressure for supplying He and the temperature of the substrate.

FIG. 9 is a graph showing a relationship between the substrate temperature and the etching rate when a HDP-TEOS (high-purity tetraethyl ortho-silicate) film 5 is formed.

FIG. 10 can be formed by accurately controlling the substrate temperature when the HDP-TEOS film 5 is formed.

FIG. 11 is a graph showing a correlation between the width w2 of the element isolating region 1 and the minimum thickness of the film that the selective epitaxial layer 2 disposed on the both sides of the element isolating region 1 is short-circuited.

### DETAILED DESCRIPTION OF THE INVENTION

An embodiment of the present invention will be described below referring to the drawings.

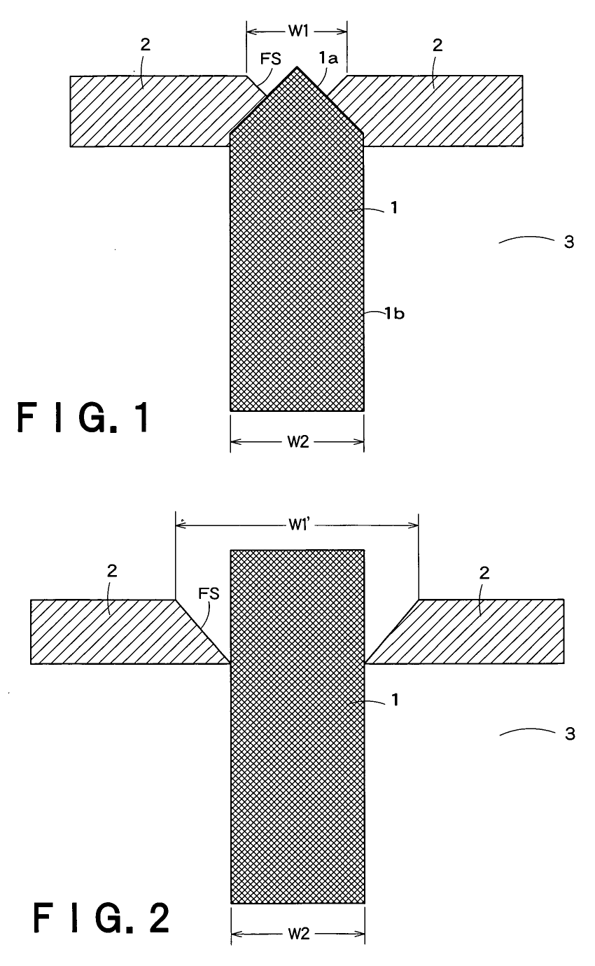

FIG. 1 is a sectional view showing a cross-sectional structure of a semiconductor device according to an embodiment of the present invention. The semiconductor device of FIG. 1 has an element isolating region 1, and a selective epitaxial layer 2 formed in both sides of the element isolating region 1. The selective epitaxial layer 2 is formed, for example, on a silicon substrate 3 or an SOI substrate. On the selective epitaxial layer 2, a transistor is formed as described later.

The tip portion 1a of the element isolating region 1 is tapered. The selective epitaxial layer 2 has a facet FS, which is an edge face slanted in a side contacting the element isolating region 1, and a tip portion of the facet FS contacts the tip portion 1a of the element isolating region 1.

The distance w1 between base portions of the facet FS of the selective epitaxial layer 2 is formed to be narrower than a width w2 of a base portion of the element isolating region 1. Thereby, the base portions of the facet FS are disposed inside the side wall of the base portion 1b of the element isolating region 1. This means that the surface parallel to the substrate surface of the selective epitaxial layer 2 becomes wider. Therefore, when impurity ions are implanted in subsequent steps, the region where impurity ions can be implanted at a desired angle is widened, impurity distribution having a desired profile can be obtained, and the fluctuation of the characteristics of a transistor can be reduced.

FIG. 2 is a sectional view showing a comparative example of the semiconductor device shown in FIG. 1, and shows an example wherein the element isolating region 1 is not tapered. In the case of FIG. 2, the facet FS of the selective epitaxial layer 2 is formed outside the sidewall of the element isolating region 1. Therefore, the distance w1′ between the base portions of the facet FS is larger than the width w2 of the element isolating region 1. In other words, the surface parallel to the substrate surface of the element isolating region 1 is narrower than the surface shown in FIG. 1. In FIG. 2, therefore, when impurity ions are implanted in subsequent steps, the region where impurity ions can be implanted at a desired angle is narrower than the region shown in FIG. 1, and the fluctuation of the characteristics of a transistor may easily occu r.

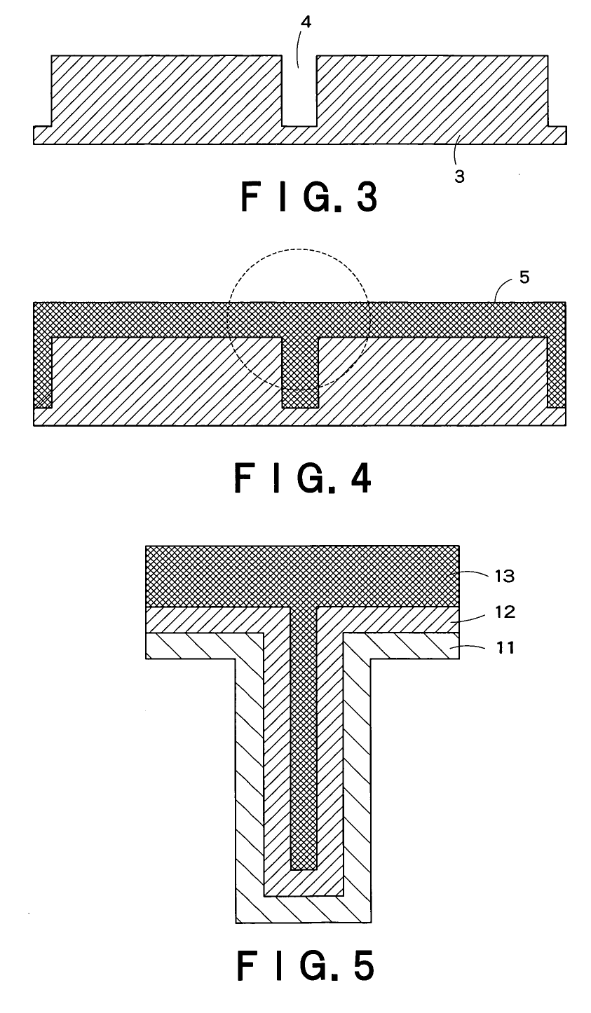

FIGS. 3 to 7 are sectional views showing the steps for manufacturing a semiconductor device according to the embodiment. First, as FIG. 3 shows, a trench 4 is formed on a silicon substrate 3 to form an element isolating region 1. A depth of the trench 4 is, for example, 0.2 μm to 0.4 μm, and a width of the trench 4 is, for example, 40 nm to 10 μm.

Next, as FIG. 4 shows, the trench 4 is filled with an HDP-TEOS (high-purity tetraethyl ortho-silicate) film 5. At this time, a pressure of helium (He) supplied to a stage on which the silicon substrate 3 is placed is controlled, and a temperature of the substrate is varied during film formation to gradually vary an etching resistance of the HDP-TEOS film 5 formed in the trench 4.

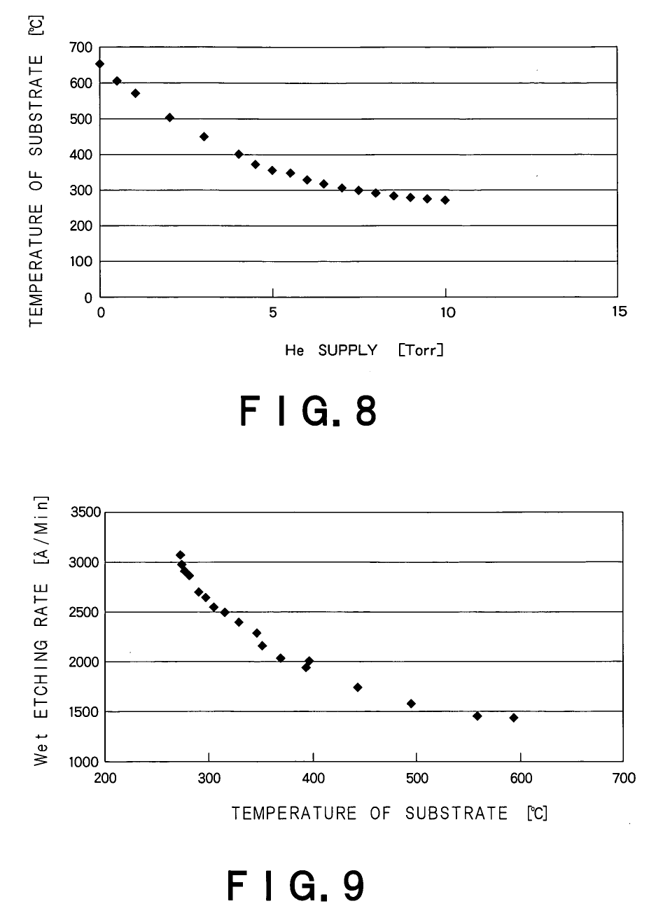

FIG. 8 is a graph showing a correlation between the pressure for supplying He and the temperature of the substrate. As FIG. 8 shows, by varying the pressure for supplying He within a range between 4 and 10 Torr, the temperature of the substrate can be varied within a range between 300 and 500° C.

Therefore, the wet-etching resistance of the HDP-TEOS film 5 can be varied. FIG. 9 is a graph showing a relationship between the substrate temperature and the etching rate when the HDP-TEOS film 5 is formed. FIG. 9 shows a dependence of the substrate temperature when the HDP-TEOS film 5 is etched using a mixed solution of hydrofluoric acid and ammonium fluoride. By varying the substrate temperature within a range between 270 and 610° C., the etching rate can be varied from 1400 to 3100 angstroms (10⁻¹⁰ m)/min.

The reason why the etching rate is thus varied by the substrate temperature is that if the film-forming temperature is lowered, the density of the oxide film is lowered, and the etching rate is elevated.

The HDP-TEOS film 5 formed using the above-described method is not easily etched in the outside of the trench 4, and is easily etched in the vicinity of the center of the trench 4.

FIG. 5 is an enlarged view in the vicinity (dotted-line portion) of the trench 4 in FIG. 4. FIG. 5 shows an example wherein an HDP-TEOS film 5 is formed by changing substrate temperatures to 500° C., 400° C., and 300° C. In FIG. 5, the first HDP-TEOS film 11 corresponds to a region where the film is formed at 500° C., the second HDP-TEOS film 12 corresponds to a region where the film is formed at 400° C., and the third HDP-TEOS film 13 corresponds to a region where the film is formed at 300° C.

Next, the formed HDP-TEOS film 5 is polished. Here, polishing by CMP (Chemical Mechanical Polishing) is first performed, and then, chemical polishing is performed. More specifically, a mixed solution of cerium oxide (CeO₂), water and a surface active agent is used. In this mixed solution, a mixed solution of hydrofluoric acid and ammonium fluoride, which has a function to etch a silicon oxide film, is added.

The pressure for pressing an abrasive cloth is 300 gf/cm² to 500 gf/cm², and the rotation speed is 50 to 100 rpm. The solution that has the function to etch the HDP-TEOS film 5 is preferably added only in initial to medium stages of polishing.

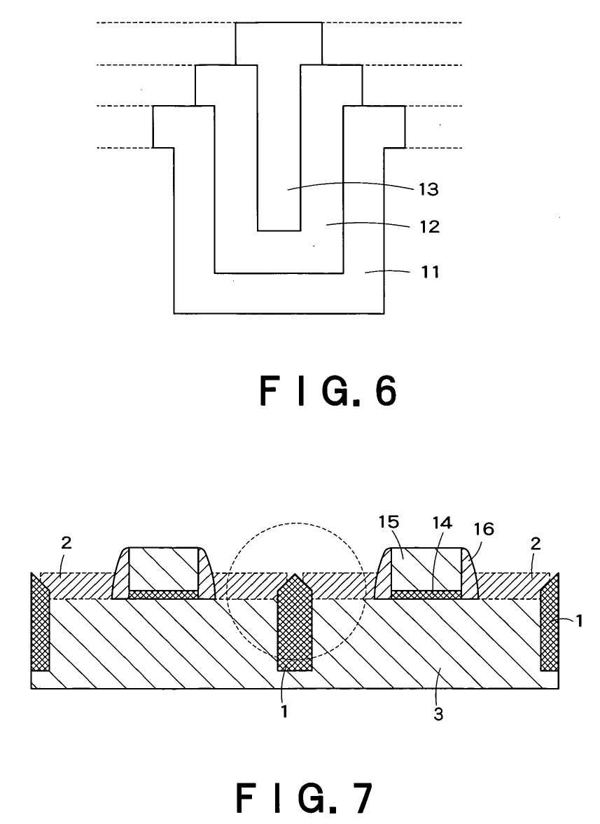

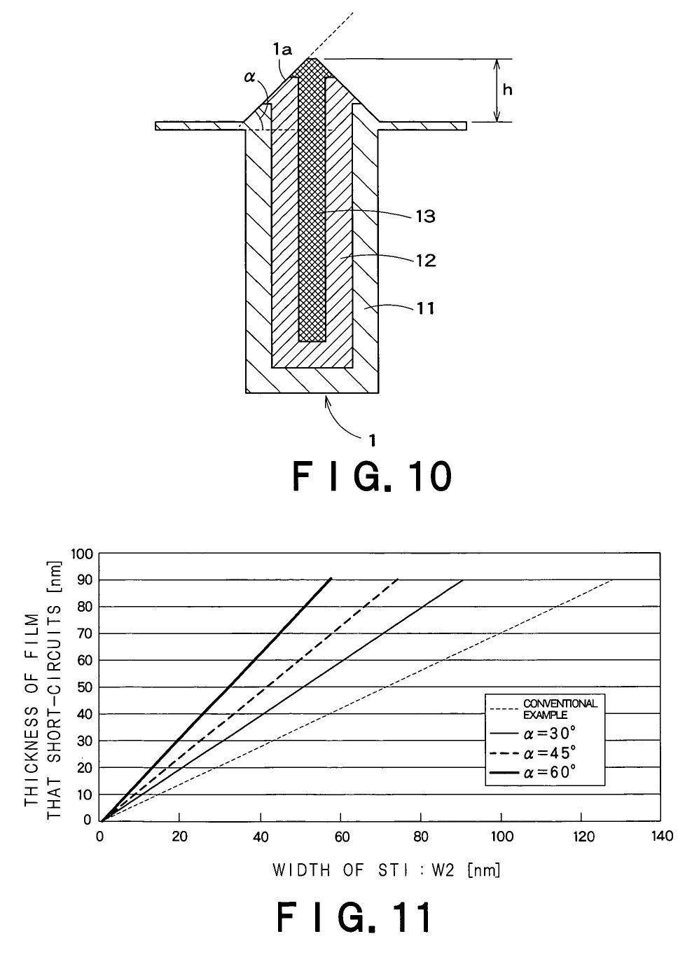

When such polishing and etching are performed, the etching quantity of the HDP-TEOS film 5 is varied depending on locations, and the tip portion of the element isolating region 1 is nearly tapered as FIG. 6 shows. In FIG. 6, although an example wherein the tip portion of the element isolating region 1 is stepwise formed is shown, the tapered shape as shown in FIG. 10 can be formed by accurately controlling the substrate temperature when the HDP-TEOS film 5 is formed.

In FIG. 10, the distance h between the shoulder portion and the tip portion of the element isolating region 1 can be controlled within ranges between 0 and 100 nm, and an angle α between the slant face of the silicon substrate 3 and the surface of the silicon substrate 3 can be adjusted within the range of 0 to 90°.

Next, as FIG. 7 shows, gate oxide films 14, gate electrodes 15, and gate electrode protection walls 16 are formed of SiN or the like, and thereafter, the surface of the silicon substrate 3 is exposed.

Actually, the tip portion 1a of the element isolating region 1 does not have a perfect tapered shape as FIG. 10, but often has stepwise shape as FIG. 6 shows.

Next, on the exposed surface of the silicon substrate 3, silicon is epitaxially grown to selectively form a selective epitaxial layer 2. More specifically, the flow rates of dichlorosilane and hydrochloric acid are controlled to be 300 to 500 sccm, and 100 to 300 sccm, respectively, and the pressure in the chamber and the temperature of the substrate are controlled to be 10 to 50 Torr and 700 to 900° C., respectively, to form a selective epitaxial layer 2 of a thickness of 20 to 50 nm. The film forming rate of the selective epitaxial layer 2 is 5 to 60 nm/min.

In the subsequent step, impurity ions are implanted into the selective epitaxial layer 2 to form the source and drain of the transistor.

Although not shown in FIG. 7, on the end surface (i.e., a surface contacting the element isolating region 1), a slanted facet FS as shown in FIG. 1 is formed. The facet FS is mainly formed with a (111) face of silicon, and the angle to the (100) face of silicon, which is the substrate surface, is set to, for example, 54.70.

FIG. 11 is a graph showing a correlation between the width w2 of the element isolating region 1 and the minimum thickness of the film that the selective epitaxial layer 2 disposed on the both sides of the element isolating region 1 is short-circuited, when the slant angle α of the tip portion 1a of the element isolating region 1 is varied. FIG. 11 shows the correlation when the slant angles α are 30°, 45° and 60°.

Since the larger the slant angle of the tip portion 1a in the element isolating region 1 is, the longer the distance h shown in FIG. 10 becomes, thereby thickening the selective epitaxial layer 2 before the short-circuiting occurs. Therefore, it is apparent from FIG. 10 that the larger slant angles are preferable. When the minimum thicknesses of the selective epitaxial layer 2 in the cases of the slant angles α=30°, 45° and 60° are compared with the minimum thickness in the case of the slant angle α=0°, it is apparent from FIG. 10 that the thickness of 1.41 times, 1.71 times, and 2.23 times can be allowed, respectively. In any cases, the base portion of the facet FS is located inside the sidewall of the base portion of the element isolating region 1.

On the other hand, if the slant angle is excessively large, the facet FS extends to the outside of the element isolating region 1 as shown in FIG. 2, and a profile of the impurity-ion implanted region is deteriorated.

As described above, when a semiconductor device in which selective epitaxial layers 2 are disposed in the both sides of the element isolating region 1 is formed, the tip portion of the element isolating region 1 is tapered or nearly tapered. Therefore, when the selective epitaxial layers 2 are formed in the both sides of the element isolating region 1, the facet FS formed on the tip surface of the selective epitaxial layers 2 is formed inside of the side wall of the element isolating region 1, and the substrate surface of the selective epitaxial layers 2 is lengthened. Therefore, when impurity ions are implanted into the selective epitaxial layers 2 in the subsequent step, the quantity of impurity ions implanted at a desired angle increases, and the profile of impurity-ion implanted region can be set to a desired value to improve the characteristics of the transistor.

### SECOND EMBODIMENT

Although an example for forming a single oxide film in a trench 4 has been described in the first embodiment, a plurality of insulation films composed of materials different from each other can also be formed in the trench 4. Any kinds of insulation films can be formed, and for example, a plurality of oxide films of different kinds, a plurality of nitride films of different kinds, or combinations of a nitride film and an oxide film can also be formed.

When such a plurality of insulation films are formed in the trench 4, it is required to form insulation films having lower etching rates in the sides closer to the inner wall of the trench 4. Thereby, when CMP and chemical etching are performed after forming the insulation film in the trench 4, an element isolating region 1 of the configuration as shown in FIG. 6 can be formed using difference in etching rates.

The steps for manufacturing a semiconductor device according to the second embodiment will be sequentially described. Since the manufacturing process diagrams are equivalent to FIGS. 3 to 6, the steps will be described referring to FIGS. 3 to 6. First, a trench 4 having a depth of 0.2 to 0.4 μm is formed in a silicon substrate 3. A width of the trench 4 is 40 nm to 10 μm.

Next, an HTO film of a thickness of 5 nm to 2 μm is formed on the surface of the silicon substrate 3 and the inner-wall surface of the trench 4. The HTO film is formed by supplying 200 to 400 sccm of each of SiH₂Cl₂ and N₂O onto the silicon substrate 3 at 700 to 800° C., and allowing them to react. By changing the film forming temperature or the gas supplying quantity, the density of the film can be changed. Thereby, the etching rate is changed.

Next, an HDP-TEOS film is formed under the same film-forming conditions as in the first embodiment.

Next, liquid polysilazane is applied into the trench 4 to completely fill the trench 4. Thereafter, an annealing treatment is performed in a water-vapor atmosphere at 200 to 500° C. to densify the polysilazane. Here, the densifying treatment is a treatment for curing liquid polysilazane by performing heat treatment. By changing the temperature for the heat treatment, the density of the film can be changed, and thereby, the etching rate can be variably controlled.

The etching rates of the oxide films formed in the trench 4 using the above-described procedures by diluted HF are in the order of HTO<HDP-TEOS<PSZ.

Next, the oxide films on the surface of the substrate are polished. Polishing is performed by the combination of CMP and chemical polishing as in the first embodiment. CMP is performed in the initial to medium stages of the polishing step. As the polishing solution, a mixed solution of cerium oxide (CeO₂), water and a surface active agent is used, and in this mixed solution, a mixed solution of hydrofluoric acid and ammonium fluoride, which has a function to etch a silicon oxide film, is added. The pressure for pressing an abrasive cloth is 300 gf/cm² to 500 gf/cm², and the rotation speed is 50 to 100 rpm.

When etching is performed during the above-described polishing step, the tip portion 1a of the element isolating region 1 become stepwise as shown in FIG. 6. More specifically, the distance h between the shoulder portion and the tip portion of the element isolating region 1 can be adjusted to 0 to 100 nm, and the slant angle α of the tip portion 1a in the element isolating region 1 can be adjusted to 0 to 90°.

Thereafter, in the same manner as in the first embodiment, a gate oxide film 14, a gate electrode 15, and a gate-electrode protection side wall 16 are formed of SiN or the like, and thereafter, the surface of the silicon substrate 3 is exposed. Then, an epitaxial layer is selectively grown on the surface of the exposed silicon substrate 3.

In the second embodiment, equivalent characteristics as shown in FIG. 11 is obtained, and the larger the slant angle of the tip portion 1a of the element isolating region 1 is, the thicker selective epitaxial layer 2 becomes.

In the second embodiment, as described above, since a plurality of insulation films having different etching rates are formed in the trench 4, the tip portion 1a of the element isolating region 1 can be formed stepwise when etching is performed during the polishing step. Therefore, the facets of the selective epitaxial layers 2 formed in the both sides of the element isolating region 1 are formed inside the side wall of the element isolating region 1, and the substrate surface of the element isolating region 1 is lengthened and the characteristics of the transistor are improved.

In the second embodiment, although an example in which oxide films composed of different materials are formed in the trench 4 was described, nitride films composed of different materials can also be formed in the trench 4. In any cases, an element isolating region 1 of the shape as shown in FIG. 6 can be obtained by forming films from materials having lower etching grade at locations closer to the inner wall of the trench 4.

In the above-described embodiments, when HDP-TEOS films 11 to 13 are formed in the trench 4, the etching resistance of the HDP-TEOS films 11 to 13 is changed by changing the pressure for supplying He and changing the temperature of the substrate. The etching resistance can also be changed by adjusting the gas flow rate, chamber pressure, plasma power, and plasma attracting power in film formation.

Etching resistance can also be changed by partially differentiating, for example, the density of the films, the composition of the films, or the composition ratio.

In the above-described embodiments, although examples in which an element isolating region 1 and a selective epitaxial layer 2 are formed on the silicon substrate 3 has been described, an SOI substrate can also be used in place of the silicon substrate 3.

What is claimed is:

1. A semiconductor device, comprising:
an element isolating region formed of an insulating film having etching rates different from each other in a side close to an inside wall and a center side of a trench formed on a semiconductor substrate; and
a selective epitaxial layer formed in both sides of the element isolating region,
wherein the element isolating region has a tip portion in a tapered shape or a stepwise shape of which a width becomes narrower at a side closer to the tip portion.

2. A semiconductor device according to claim 1,
wherein the selective epitaxial layer has a facet which contacts the element isolating region at an angle slanted from a substrate surface, the facet being disposed inside of a sidewall of a rear end portion in the element isolating region.

3. A semiconductor device according to claim 2,
wherein the angle slanted from the substrate surface of the tip portion in the element isolating region is set to dispose the facet inside of the sidewall of the rear end portion in the element isolating region.

4. A semiconductor device according to claim 1,
wherein the insulating film has a plurality of insulating regions each having different etching rate, the insulating regions having the lower etching rate being disposed in a side closer to the inside wall of the trench.

5. A semiconductor device according to claim 4,
wherein the element isolating region has the insulating region formed at higher temperature in a side closer to the inside of the trench.

6. A semiconductor device according to claim 1,
wherein the element isolating region is formed at least three different temperatures.

7. A semiconductor device according to claim 1,
wherein the insulating film includes HDP-TEOS (high-purity tetraethyl ortho-silicate) film.

8. A semiconductor device according to claim 1,
wherein the insulating film includes a nitride.

9. A semiconductor device according to claim 1, further comprising:
a first transistor formed by using the selective epitaxial layer disposed in one side of the element isolating region; and
a second transistor formed by using the selective epitaxial layer disposed in the other side of the element isolating region.

10. A semiconductor device according to claim 1,
wherein the semiconductor substrate is an SOI (Silicon On Insulator).

11. A method of fabricating a semiconductor device, comprising:
forming a trench in a region to form an element isolating region on a semiconductor substrate;
forming an insulating film having etching rates different from each other in a side close to an inside wall and a center side of a trench formed on a semiconductor substrate;
eliminating a portion of the insulating film by a CMP (Chemical Mechanical Polishing) process and an etching process to form the element isolating region having a tip portion in a tapered shape or a stepwise shape of which a width becomes narrower at a side closer to the tip portion; and
forming silicon grown epitaxially in both sides of the element isolating region to form a selective epitaxial layer.

12. A method of fabricating a semiconductor device according to claim 11,
wherein a facet which contacts the element isolating region at an angle slanted from a substrate surface is formed on an end surface of the selective epitaxial layer, the facet being disposed inside of a sidewall of a rear end portion in the element isolating region.

13. A method of fabricating a semiconductor device according to claim 12,
wherein the angle slanted from the substrate surface of the tip portion in the element isolating region is set to dispose the facet inside of the sidewall of the rear end portion in the element isolating region.

14. A method of fabricating a semiconductor device according to claim 11,
wherein the insulating film is formed of a plurality of insulating regions each having different etching rate, the insulating regions having the lower etching rate being disposed in a side closer to the inside wall of the trench.

15. A method of fabricating a semiconductor device according to claim 14,
wherein the element isolating region has the insulating region formed at higher temperature in a side closer to the inside of the trench.

16. A method of fabricating a semiconductor device according to claim 11,
wherein the element isolating region is obtained by forming at least three different temperatures.

17. A method of fabricating a semiconductor device according to claim 11,
wherein the insulating film includes HDP-TEOS (high-purity tetraethyl ortho-silicate) film.

18. A method of fabricating a semiconductor device according to claim 11,
wherein the insulating film includes a nitride.

19. A method of fabricating a semiconductor device according to claim 11,
wherein a first transistor is formed by using the selective epitaxial layer disposed in one side of the element isolating region; and
a second transistor is formed by using the selective epitaxial layer disposed in the other side of the element isolating region.

20. A method of fabricating a semiconductor device according to claim 11,
wherein the semiconductor substrate is an SOI (Silicon On Insulator).
